(19) United States
(12) Patent Application Publication
(10) Pub. No.: US 2025/0208185 A1
(43) Pub. Date: Jun. 26, 2025

(54) SCALABLE HPEM EFFECTOR ARRANGEMENT AGAINST THREATS HAVING A PLURALITY OF TARGETS AND METHOD FOR COMBATTING A THREAT

(71) Applicant: Diehl Defence GmbH & Co. KG, Überlingen (DE)

(72) Inventors: Martin Schwarz, Überlingen (DE); Robert Stark, Bad Windsheim (DE)

(21) Appl. No.: 18/999,064

(22) Filed: Dec. 23, 2024

(30) Foreign Application Priority Data
Dec. 22, 2023 (DE) 10 2023 005 328.7

(51) Int. Cl. G01R 29/08

(52) U.S. Cl. CPC G01R 29/0892; G01R 29/0814

(57) ABSTRACT

An effector arrangement for combatting a threat which includes targets, contains HPEM sources, an input and/or a memory for a mission specification (76) and/or a prioritization for combatting a threat and a control device, which assigns the threat scenarios and target classes and, depending thereon, HPEM characteristics and, depending thereon, HPEM sources, and which activates the assigned HPEM sources depending on the threat scenarios, target classes, HPEM characteristics, mission specifications and/or prioritizations to combat the threat. A method for combatting the threat includes providing the mission specification and/or the prioritization. The control device assigns the threat scenarios and target classes to the threat and, depending thereon, the HPEM characteristics and, depending thereon, the HPEM sources, and activates the assigned HPEM sources depending on the threat scenarios, target classes, HPEM characteristics, mission specifications and/or prioritizations to combat the threat.

### CROSS-REFERENCE TO RELATED APPLICATION

This application claims the priority, under 35 U.S.C. § 119, of German Patent Application DE 10 2023 005 328.7, filed Dec. 22, 2023; the prior application is herewith incorporated by reference in its entirety.

### FIELD AND BACKGROUND OF THE INVENTION

The invention relates to an HPEM effector arrangement (High Power Electro-Magnetics), which contains at least two HPEM sources for emitting respective HPEM pulses. The invention also relates to a method for combatting a threat in the form of at least one target by using an effector arrangement.

### DESCRIPTION OF THE RELATED ART

There are HPEM effector systems in the form of array systems and technology based on vacuum and/or spark gap technology; Narrow Band (NB), Wide Band (WB), Ultra Wide Band (UWB) HPEM systems that emit a singular frequency with a very low bandwidth or a center frequency with a bandwidth of up to 100% or higher.

Depending on the technology, the radiated waves or HPEM pulses of up to several 100 MW or GW have the same wavelength or pulse shape and thus in each case a corresponding center frequency and bandwidth. Such systems are usually specifically configured and well suited for defense against threats or targets of a defined target class (for example UAS—unmanned aerial systems or IED—improvised explosive devices) or a group of targets within a target class with a similar sensitivity/sensitivity spectrum.

By phase-synchronous activation of a number of identical systems/antennas (sources) in an array or the synchronization of a number of distributed systems, wave trains and pulses can be time-coordinated and synchronized, so that the wavefronts in the far field are constructively superimposed. This allows the field amplitude in the far field and thus the range of the entire system (effector arrangement) to be increased and the effect to be focused on the target.

Though the use of a targeted time shift of the phase fronts of the individual systems (sources) with respect to one another, the alignment or the radiating angle of the HPEM beam or the radiated wavefront (pulse) can be manipulated or set (so-called “beam steering”).

The rather large temporal jitter, for example in the case of systems based on spark gap technology, can be seen as a disadvantage. A high temporal jitter ultimately leads to a high level of inaccuracy in the synchronization of the systems (sources), so that only a very limited number of such systems can be meaningfully synchronized with one another. This limits the increase in range as a result of parallel, synchronized operation of such installations and systems (effector arrangement).

The radiating elements/antennas (sources) are in each case in an array or may also be locally distributed. The primary energy (for feeding the sources) is usually provided by a central energy supply. In the case of delocalized array systems, a decentralized energy supply (battery, network, etc.) is also possible.

The synchronization must take place by way of a master timer. A correspondingly precisely timed synchronization for the targeted constructive superpositioning of the wavefronts of a number of distributed systems (sources) is difficult due to the high temporal jitter, in particular at higher radiated frequencies.

Newer installations (sources) based on semiconductor technology emit singular frequencies with a very small bandwidth and significantly lower power. As a result, the range of application against different targets and target classes is very limited.

### SUMMARY OF THE INVENTION

It is accordingly an object of the invention to provide a scalable HPEM effector arrangement against threats having a plurality of targets and a method for combatting a threat, which overcome the hereinafore-mentioned disadvantages of the heretofore-known effectors and methods of this general type and which provide improvements in relation to combatting a threat.

With the foregoing and other objects in view there is provided, in accordance with the invention, an effector arrangement as described below. Preferred or advantageous embodiments of the invention and of other invention categories become apparent from the further claims, from the following description and from the appended figures.

The effector arrangement serves or is set up for combatting a threat. The threat contains or presents itself in the form of at least one, in particular a number of targets. The effector arrangement contains at least two HPEM sources. Each of the HPEM sources is set up to emit respective HPEM pulses to the threat. At least two of the sources can be activated independently of one another for the emission of the HPEM pulses, in particular any types of pulses at any points in time, in any directions, so that, for example, two different targets can be irradiated individually.

The effector arrangement contains an input and/or a memory. At least one mission specification for or in relation to the combatting of the threat and/or a prioritization of targets constituting the threat can be entered into the effector arrangement by way of the input or stored in the memory. In other words, the corresponding variables can in this way be provided to the effector arrangement. Mission specification and/or prioritization thus lead to a combat scenario in relation to the threat. In other words, this determines which targets are to be combatted, for example, in which order with which pulses.

The effector arrangement contains a control device. This is set up to proceed as follows or to perform the following method:

The threat is assigned at least one of a number of predefinable threat scenarios. This classifies the threat, so that, for example, certain pre-configured strategies can be adopted to combat it.

The threat is assigned at least one of a number of predefinable target classes. In particular, a respective target class relates to a respective target constituting the threat. This, too, serves for determining a strategy for combatting the threat—in particular in relation to the targets constituting the threat.

The threat scenario therefore describes the threat in its entirety, in particular as a conglomerate of targets. The target classes describe the respective targets as individually as possible.

The threat is assigned at least one of a number of predefinable HPEM characteristics. This happens depending on the assigned threat scenarios and/or the assigned target classes. The HPEM characteristics describe the properties, for example resistance, of the threat, in particular its targets in relation to irradiation with different HPEM pulses.

The threat is assigned at least one of the sources. This also happens depending on the assigned threat scenarios and/or the assigned target classes and/or the assigned HPEM characteristics. In other words, depending on the threat/targets and their properties, sources of the effector arrangement which can combat the threat or the corresponding targets as successfully as possible by sending HPEM pulses there are selected or assigned.

Then the sources for combatting the threat are activated so that they emit the pulses. On the one hand, this happens depending on the assigned threat scenarios and/or the assigned target classes and/or the assigned HPEM characteristics. On the other hand, this happens depending on the mission specifications and/or the prioritizations. In other words, the sources are thus operated suitably in order to optimally defend against the threat. This happens in particular by adjusting the mode of operation of the sources, for example pulse energy, pulse rate, pulse shape, etc. In the assignment of the sources, those that are most likely to combat the threat are chosen, such as sources that emit HPEM pulses for which the threat is particularly sensitive according to its HPEM characteristics.

In particular, the effector arrangement is suitable for combatting a threat constituted simultaneously by a number of targets, with the number of targets representing, for example, a swarm of drones. Each of the drones is one of the targets. In other words, a method is performed in the effector arrangement according to the invention or its control device according to the invention, as will be explained again further below.

According to the invention, a scalable HPEM effector module is thus obtained in particular. This results in particular in an HPEM method and system (effector arrangement) for simultaneously combatting multiple electronic targets (for example UAS—unmanned aerial systems, mini-UAS swarms, C4I—command, control, communications, computers, intelligence). By specific adaptation, synchronization and suitable activation of one/a number of modules/submodules, different targets at different locations can be combatted simultaneously with different frequencies and beams. This results in particular in a semiconductor-based, fully integrated module that allows scaling and specific adaptability.

In a preferred embodiment, at least one of the target classes is one that is specifically adapted to a sensitivity of the target with respect to HPEM pulses. In other words, the target class then defines different targets that are different in sensitivity in relation to HPEM pulses. This makes it possible to activate the sources differently in order to make the best use of the respective sensitivity and to combat the targets as effectively as possible.

In a preferred embodiment, the effector arrangement has at least one module. Each of the modules contains at least one of the sources. Relevant sources are therefore organized in modules, in particular a number of modules. The modules are configured, for example, in the form of structural units. The effector arrangement can thus, for example, be scaled particularly easily by removing or adding or exchanging modules.

In a preferred variant of this embodiment, at least one of the modules is configured as a semiconductor-based fully integrated module. This allows a particularly flexible activation of the module or of a number of sources within the module, in particular their optional interconnection to form submodules, see below.

In a preferred variant of this embodiment, at least one of the modules contains at least two of the sources. These sources are then disposed in the form of an array in a fixed relative position in relation to one another. Such arrays are suitable in particular for synchronizing their sources in time or phase, for example in the same phase to allow constructive superpositioning for power amplification or with a controlled phase shift to allow superpositioning for beam alignment (beam steering).

In a preferred embodiment, the effector arrangement contains at least three sources. These three or more sources can then be optionally and modifiably combined to form submodules of at least two sources each. The control arrangement is set up to activate the sources organized as the current submodule (currently) jointly and independently of other sources. In particular, all sources of the submodule are exclusively activated together in each case. This happens, for example, according to a submodule-related group rule for the submodule's group of sources. As a result, different and/or different numbers of sources can be organizationally combined to form the submodule, depending on the requirements, in order to respond individually to a respective threat. For example, in a module with new sources, all new sources can be operated synchronously as a single submodule in order to combat a single HPEM-insensitive target. In another situation, the same new sources are organized into three submodules, each with three sources, in order to simultaneously combat three more sensitive targets (fewer sources needed) by one of the submodules for each.

For a preferred embodiment, the invention assumes that the threat contains at least two targets. Or the corresponding embodiment is particularly suitable for combatting such threats. The control device is set up to operate the effector arrangement for at least two of the targets in parallel and independently of one another. The invention therefore assumes that threats having a plurality of targets are also to be combatted, with the defense against or combatting of the targets being intended to take place simultaneously. This is possible as a result of the parallel independent operation. In particular, one of the aforementioned submodules is chosen for each target, with the submodules being put together from the available sources depending on the type and sensitivity of the targets. This makes simultaneous combatting of multiple targets possible. Each of the targets can be combatted individually.

In a preferred embodiment, the control device is set up to activate at least two of the sources in that they are synchronized with one another for emitting the HPEM pulses. In particular, as already explained above, this happens within a submodule. Synchronization is, as also explained above, for example, same-phase operation for far-field amplification (superpositioning) or phase-shifted operation for beam steering.

In a preferred embodiment, the control device contains an AI device or is configured as an AI device (artificial intelligence). Using methods of AI, which can be used in this case in a conventional manner, it is possible in particular to optimally divide effector arrangements including a variety of sources, for example into submodules, in order to defend against a threat including a large number of targets in parallel and effectively.

With the objects of the invention in view, there is concomitantly provided a method for combatting a threat in the form of at least one target by using the effector arrangement according to the invention. In the method, at least one mission specification and/or at least one prioritization of targets in relation to the combatting of the threat is provided. The control device assigns the threat at least one of a number of predefinable threat scenarios, assigns the threat at least one of a number of predefinable target classes and, depending on the assigned threat scenarios and/or the assigned target classes, assigns the threat at least one of a number of predefinable HPEM characteristics. The control device assigns the threat at least one of the HPEM sources depending on the assigned threat scenarios and/or the assigned target classes and/or the assigned HPEM characteristics.

The control arrangement then activates the assigned HPEM sources to combat the threat. This happens depending:
on the one hand on the assigned threat scenarios and/or the assigned target classes and/or the assigned HPEM characteristics, and
on the other hand depending on the mission specifications and/or the prioritizations.

The method and at least some possible embodiments thereof and the respective advantages already have been explained analogously in connection with the effector arrangement according to the invention.

The invention is based on the following findings, observations or considerations and has furthermore the following preferred embodiments. These embodiments are also sometimes referred to as “the invention” for the sake of simplicity. The embodiments may in this case also contain parts or combinations of the aforementioned embodiments or correspond to them and/or possibly also include embodiments which have not yet been mentioned.

The invention is based on the concept of creating an HPEM method and system (effector arrangement) for simultaneously combatting a threat in the form of multiple electronic targets (for example UAS, mini-UAS swarms, C4I, IED) in different scenarios. It is intended to be possible to combat a number of identical and/or different targets at different locations within the effective range (for example air (UAS, UAS-IED) and ground target (for example IED, C4I) simultaneously. The aim is to create a specifically adaptable, synchronizable, semiconductor-based HPEM module and system that allows different frequencies with identical and/or different bandwidths and identical and/or different pulses and field strengths to be simultaneously generated, specifically adapted, synchronized and directed/made to act in a targeted manner against the threat together and/or separately on identical and/or similar and/or different targets, which may be located at the same and/or different locations (for example ground/air; C-UAS & C-IED scenario) at equal and/or different distances.

Therefore, in particular an HPEM method and/or fully semiconductor-based modular, scalable system and modules with corresponding capabilities are created: This is because it is possible with powerful HPEM pulses (100s of MW-GW) to combat a number of different targets of different target classes with different sensitivities at different locations and in different scenarios simultaneously.

According to the invention, a method and system (effector arrangement) for providing simultaneous defense against and combatting of multiple, identical and different electronic threats and targets (for example UAS, mini-UAS swarms, C4I) is obtained. The system contains/is formed of one or more identical and/or similar and/or different synchronizable and/or specifically adaptable sources, in particular in the form of modules. The specific adaptation of a number of modules and/or submodules allows the simultaneous radiation of identical, similar and/or different frequencies, frequency ranges, center frequencies and beams. The phase control of the semiconductor-based systems in the sub-ns range allows the alignment of the beams from one and/or more (sub) modules/sources with one and/or a number of identical, similar and/or different targets, target classes or target groups.

The semiconductor-based module and submodule configuration makes the system scalable and specifically adaptable. The method can be scaled/specifically adapted/adjusted to different scenarios. The module(s)/system can control or instigate the combatting of one or more targets in a manner that is centrally controlled, remotely controlled and/or autonomous/partially autonomous by AI. AI makes a significant contribution to the efficient, targeted control of the various components, submodules, modules and systems. This applies not only to the identification and classification of the threat but also to the selection and targeted combatting of the threats and also to the effect-optimized control of the individual systems/components/modules as well as of a number of systems and modules.

As a result of higher-level control by AI, a number of identical and/or different modules/submodules/systems (effector arrangements) and components can be selected, combined and coordinated and used sequentially and/or simultaneously in a controlled and effect-optimized manner against individual and/or a number of targets, identical/similar and/or different targets/target groups and target classes in identical and different scenarios.

This produces a method and system for providing simultaneous defense against different electronic threats based on one or more semiconductor-based, synchronizable and threat-specifically adaptable, scalable HPEM (effector) modules.

This produces a semiconductor-based, modular, fully integrable/integrated HPEM effector module/system. Each module includes not only the energy supply including intermediate storage and processing of energy, but also the control, phase control and synchronization of the submodules and the interconnection of the antennas including the feed-in network. The dimensions and geometrical shapes of the modules can result in correspondingly meaningful/possible integration possibilities or application cases, taking into account the frequencies/frequency ranges to be radiated, as well as the dimensioning of the antenna elements/the antenna and thus the effect. For example, cuboidal modules with antenna elements for example on one (or more) of the long sides, but also cylindrical modules with the radiating elements on for example one or both cylinder base surfaces, but also many other combinations of meaningful geometries and dimensions are conceivable. The antenna/antenna elements of each module/submodule is formed of at least one and/or a number of antenna elements (for example monopole, dipole, patch antenna, antenna structures with meta-materials, active and/or passive control elements in the antenna elements or other suitable configurations) which, depending on the radiated power to be achieved or required and the frequencies/frequency ranges to be radiated, can be passively or actively operated while coupled, intercoupled or interconnected with one another, with passive and/or active elements/control elements/specifically-adapting elements. The active and/or passive switching of individual antenna elements/control elements/specifically-adapting elements is possible.

As a result of the targeted influencing/control/interconnection of individual/a number of, identical and/or similar and/or different antenna elements and/or antenna structures and/or active/passive elements in the antenna structures and the corresponding activation by way of AI, it is possible to realize individually and/or simultaneously different antenna configurations and thus different radiated pulse shapes and wavelengths with different radiated bandwidths in a single module. The distance between the individual antenna elements and/or structures does not have to be uniform or linear within the module or across modules. For example, harmonics or resonances, i.e. multi-band configuration in the individual antenna elements in connection with the response of array columns or rows of different geometric distances can be chosen in dependence on the required radiation properties and the radiation frequency. The operating manner and the operating mode can also be extended by the operation and suitable interconnection of a number of modules/submodules in one system. The operation of a number of modules in an array is possible. The modules can in each case be operated separately and/or in groups or as a whole. As a result of targeted synchronization and influencing of the phase position between the different radiated frequencies, center frequencies, waves and/or pulses, the HPEM beams can be focused and the range can be correspondingly scaled, increased and adjusted. As a result of the exact temporal synchronization of the semiconductor-based elements in one module, in a number of modules, groups and systems in the sub-ns and ps range (also sub-ps possible), the method is scalable and also transferable to spatially distributed systems (distributed modules, arrays and systems). In addition, the exact temporal synchronization makes it easy to realize beam steering for combatting and tracking targets.

The control and activation of the individual antenna elements/antennas/antenna modules and subsystems as well as the individual/a number of HPEM modules/submodules and systems takes place by way of an integrated and/or higher-level AI. As a result, the respective module and antenna configurations, the radiated frequencies/frequency ranges and pulse shapes can be adjusted to the respective targets/target classes and/or target groups individually or in combination with one another and the effect can be increased efficiently. The radiated pulse shapes, frequencies and bandwidths can thus be adjusted in a targeted manner to the target spectrum as well as to the effect and effective range. The alignment of the HPEM beams individually and/or combined in groups is possible.

Taking into account a sensor unit, a tracking unit and a control unit for adjusting and tracking the beam alignment (electronic beam steering), the target(s) can be held in the target beam and exposed to it over a longer period of time. As a result of grouping and interconnecting different subregions of a module or a number of submodules or modules, a number of different beams with identical and/or different frequencies/frequency ranges/bandwidths and pulse characteristics can also be simultaneously directed on, and used to combat, the same target (for example a single target or a swarm). As a result of the high flexibility in the wiring of the individual antenna elements, antenna groups and modules and the exact timing and synchronization with one another, which is selected and controlled by way of AI, a number of beams can also be simultaneously directed on a number of identical and/or different targets at the same and/or different locations. This requires exact temporal control and correspondingly small temporal jitter, which cannot be realized with other technologies. The targets must be within the possible range of rotation and effect of the HPEM beam/beams or of the module/modules or of the system/systems.

This produces a self-sufficient/autonomous/partially autonomous surface-conformally integrable, scalable, fully semiconductor-based HPEM effector module for different carrier platforms (land, air, sea) for, for example, MGCS (Main Ground Combat Systems) and FCAS (Future Combat Air Systems).

The invention has the advantage that an HPEM method and system for the simultaneous combatting of multiple electronic identical/similar and/or different targets (for example UAS, mini-UAS swarms, C4I, IED) results in identical/similar and/or different scenarios at the same/similar and/or different locations.

This produces a semiconductor-based fully integrated, self-sufficient and/or autonomous, modular, specifically adaptable, AI-controlled scalable HPEM effector system/module for the simultaneous and/or sequential combatting of a number of different and/or identical electronic targets/target classes and/or target groups, which may have different sensitivities and different sensitive frequencies and/or sensitive spectral ranges.

This produces a semiconductor-based HPEM effector module and system for providing simultaneous controlled and/or self-sufficient and/or autonomous defense against and combatting of different targets (for example UAS, Mini-UAS, Mini-UAS swarms, C4I), which may be close to one another and/or at different locations at the same and/or different effective ranges/distances (for example simultaneous combatting of swarm targets and single targets; air targets and/or ground-level targets or the like). The targets may have identical and/or similar and/or different sensitive frequencies and/or frequency ranges/spectral ranges/center frequencies. As a result of the semiconductor-based modular, partially and/or fully integrated configuration, the module/system should be scalable and easily adaptable, adjustable and specifically adaptable and scalable to different requirements from different applications and scenarios. The electronic tuning of the active/passive antennas/elements/structures and the specific adaptation of a number of modules/submodules/systems allows different targets to be simultaneously and/or sequentially exposed to or combatted with identical/similar and/or also different frequencies and HPEM pulses and HPEM beams. As a result of the modular semiconductor-based configuration and corresponding activation, the alignment of a number of and/or different beams with one and/or a number of targets of identical, similar and/or dissimilar type is also possible. The module(s) and/or system(s) is/are scalable and can be adapted/adjusted/scaled to the target(s) and the scenario(s). Operation may take place in a self-sufficient, autonomous or remotely controlled manner, by way of an internal/external timer/master timer and/or with human in the loop (HITL) or manually. Control by way of AI allows actively controlled adjustment of the modules and systems to the respective current and currently changing requirements from the target spectrum and the scenarios in “real time.”

The invention is suitable for:
1. an HPEM system in a stationary form or on mobile platforms for various applications (for example for counter-UAS as vehicle protection, C-UAS field camp protection, CIED, etc.);
2. an HPEM system in a mobile form for land application integrated on a vehicle for self-protection within the scope of close and immediate area protection and MGCS (main ground combat system) for various applications (for example counter UAS, C-IED, convoy protection, etc.);
3. an HPEM system in a mobile form for air and sea applications integrated on an aircraft, drone or ship for self-protection within the scope of close and immediate area protection for various applications (for example counter UAS, C-IED, BootStop etc.);
4. Distributed HPEM modules and/or systems with swarming ability (for example UAS, drones) for coordinated actions for protection or for attack. Integration on mobile and/or flying platforms (for example FCAS, NGF, LW, RC, UAV, UAS, mini-UAS, etc.).

Other features which are considered as characteristic of the invention are set forth in the appended claims.

Although the invention is illustrated and described herein as embodied in a scalable HPEM effector arrangement against threats having a plurality of targets and a method for combatting a threat, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE FIGURES

FIG. 1 is a symbolic, perspective, block diagram showing the basic structure of an effector arrangement according to the invention;

FIG. 2 is a diagrammatic, plan view of an alternative effector arrangement with supply elements;

FIG. 3 is a front-elevational view of the alternative effector arrangement with exemplary sources;

FIG. 4 includes various elevational views, including a detail, of an alternative effector arrangement in the combatting of a threat;

FIG. 5 is a perspective view showing an alternative deployment scenario of an effector arrangement on an aircraft;

FIG. 6 is a perspective view showing an alternative coordinated deployment scenario of a number of effector arrangements; and

FIG. 7 is a flow diagram of a method according to the invention.

### DETAILED DESCRIPTION OF THE INVENTION

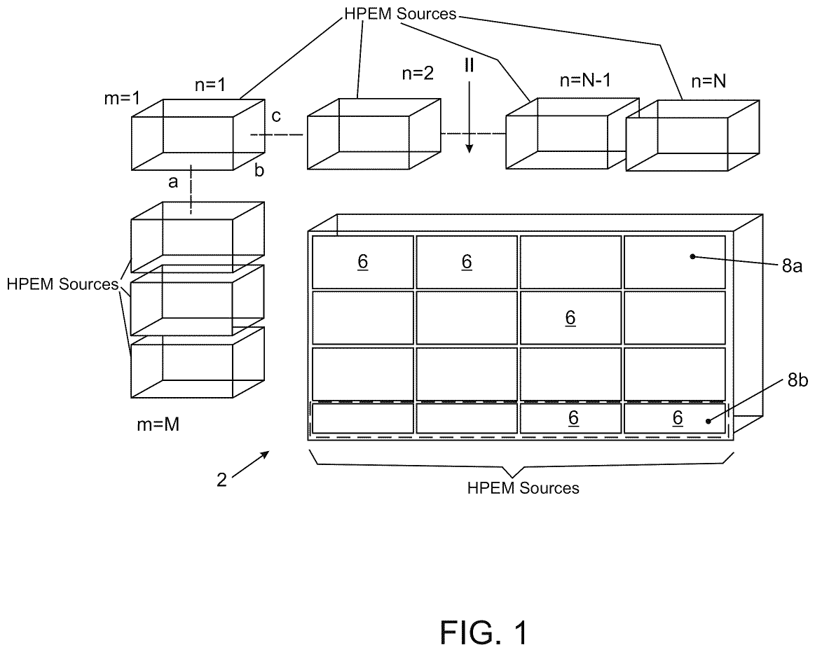

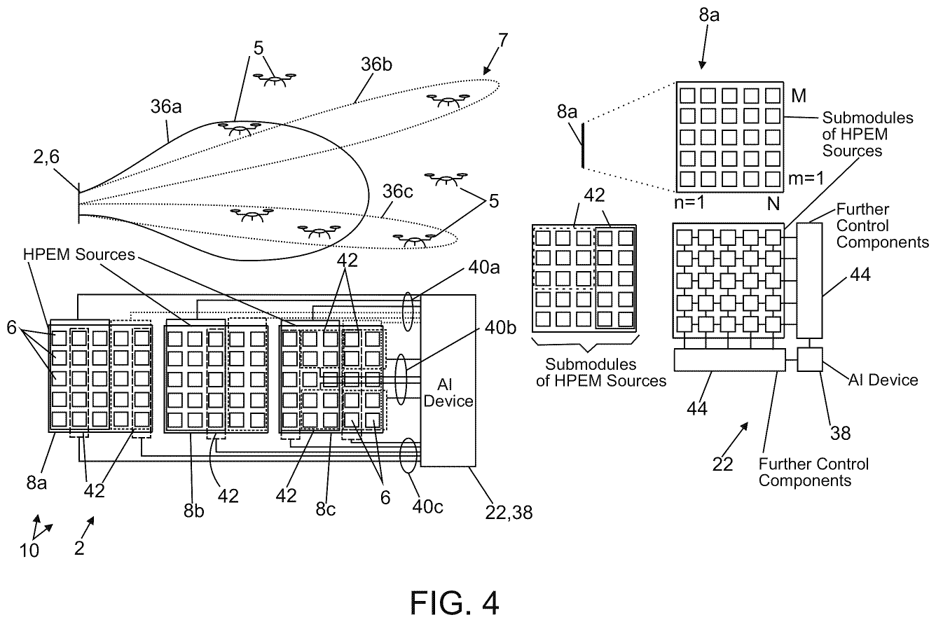

Referring now to the figures of the drawings in detail and first, particularly, to FIG. 1 thereof, there is seen a self-sufficient, autonomous, scalable semiconductor HPEM effector arrangement 2 for providing defense against or combatting an enemy electronic threat 4 (see FIG. 4). In the example, the effector arrangement 2 contains sixteen HPEM sources 6, which are disposed in columns n=1, 2, . . . N and rows m=1, 2, . . . M, i.e. as an N×M array 10 (also symbolically indicated for the general case).

The effector arrangement 2 is organized in this case into altogether two modules 8a,b (also called “effector modules”), which may also be referred to as basic modules. The module 8a contains twelve sources 6, disposed in a 4×3 array. The module 8b contains four sources 6 in the form of a 4×1 array 10. This produces the effector arrangement 2 as an HPEM module array with two different (basic) modules 8a,b. The module 8b is indicated by an implied frame to distinguish it from the module 8a.

The dimensions a,b,c of each source 6 are a function of various parameters such as frequency, bandwidth, number and density of elements, permeability number and permittivity number. The configuration of the dimensions depends on or is determined by the to-be-radiated frequencies, pulses, field strengths, bandwidths and material properties to be realized (for example refractive indices, meta-materials, etc.).

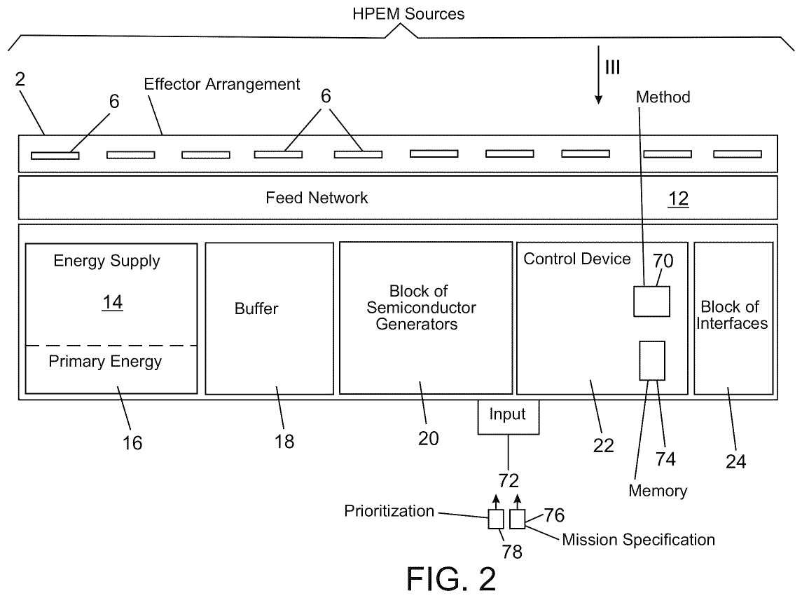

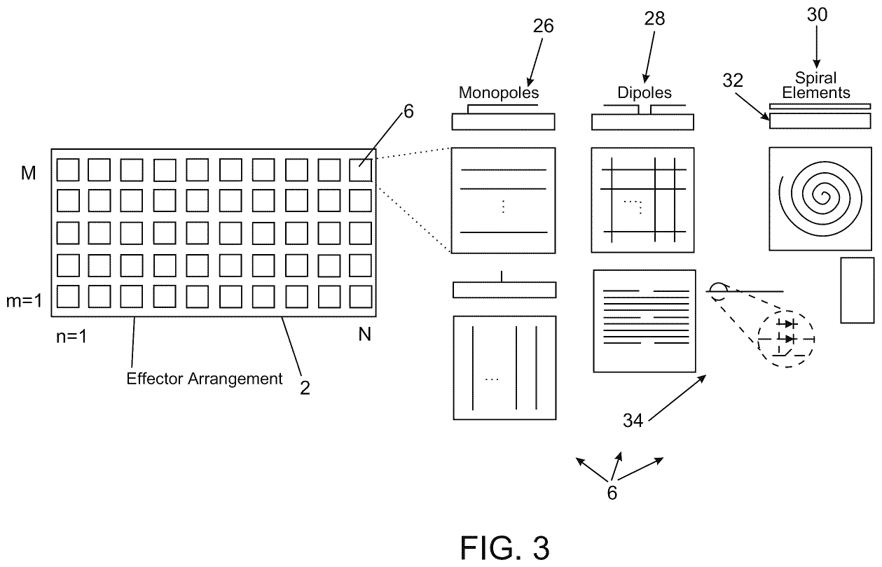

FIG. 2 and FIG. 3 show an alternative effector arrangement 2 as a 10×5 array 10. FIG. 2 shows a plan view, comparable to the direction of the arrow II in FIG. 1. The sources 6 are indicated in this case in the form of N=10 antenna elements. The sources 6 form in their entirety a kind of front panel, which only contains the antenna elements in the form of the sources 6. FIG. 2 also shows other components that are present for supplying the effector arrangement 2:

A feed network 12 also fulfils the purpose of a power division. An energy supply 14 is fed from primary energy 16. A buffer 18 serves for intermediate storage and processing of energy. A block 20 contains in particular the semiconductor HPEM/HV generators for supplying the sources 6. A control device 22 associated with the effector arrangement 2 serves for controlling and synchronizing the sources 6. A block 24 contains interfaces.

FIG. 3 shows the front view of the effector arrangement 2 from FIG. 2 in the direction of the arrow Ill in FIG. 2, that is to say the aforementioned front panel with the sources 6 in the form of antenna elements. For one of the sources 6 (indicated by dashed lines), possible embodiments of the sources 6 are shown in the form of basic antenna elements. Merely by way of example, these may be: monopoles 26, dipoles 28 or spiral antennas 30. These may have in particular (indicated by the arrow 32): reflectors/absorbers/meta-material with passive/active elements having properties which can be activated/set. They may include (indicated by the arrow 34, examples only): electronic and/or mechanical elements/components/switching elements/meta-material for the selection/control of frequency, bandwidth, directional characteristic, radiation behavior.

Altogether, the sources 6 are characterized by:
active/passive elements for switching on/off/activation, specific adaptation and tuning of the frequency range and the bandwidth,
the number, distance and dimensioning depending on the frequency and bandwidth to be realized,
antenna elements can be switched on and off, combinable into group elements.

When seen together, FIGS. 2 and 3 therefore show a semiconductor-based HPEM effector module (basic module) in the form of the effector arrangement 2 and embodiments of the basic antenna elements. The following properties result:
beam steering capability,
multi-beam and multi-frequency capability (different beams and/or frequencies, different alignments-simultaneous and/or temporally synchronized/specifically adapted to one another); focusing on and specifically adapting to the target, specifically adapting the frequency and/or pulse shape (rise time, duration, vibration behavior, energy, power etc.) and/or amplitude)),
antenna element can be activated individually,
formed of for example monopole, dipole, spiral antenna,
with/without meta-material,
I/O communication,
synchronization,
fully integrated in one module,
synchronization of a number of modules,
HPEM pulses UWB, WB, NB,
voltages in the range of several kV to MV,
power several MW to GW total power,
patch antenna, monopole, dipole, dielectric lens
meta-material lens,
multiple beams within an aperture area,
simultaneous defense against multiple threats (for example C-UAS, C-IED, C4ISTAR targets).

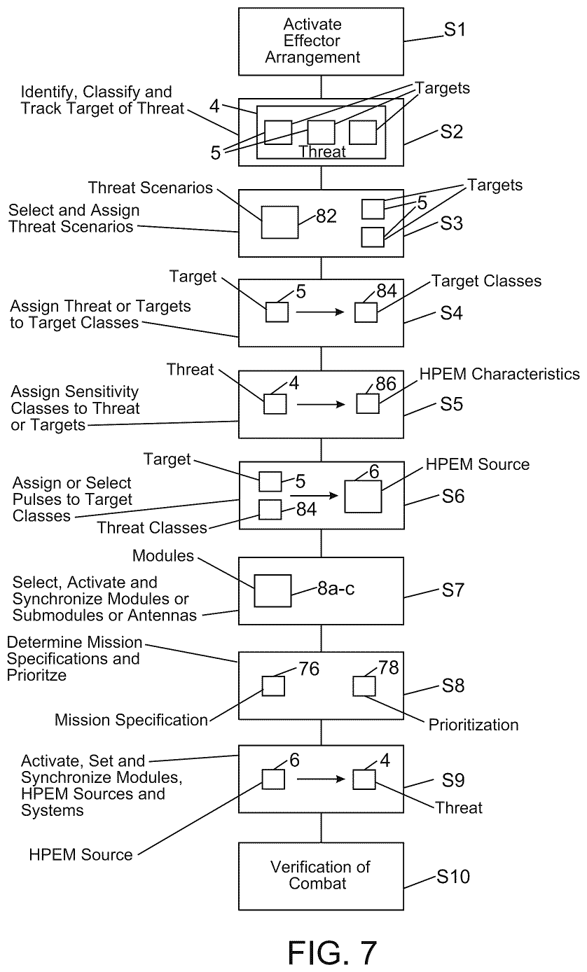

FIG. 2 also symbolically shows that a method 70 (see FIG. 7) is performed in the control device 22. It is also symbolically indicated that the effector arrangement 2 has an input 72 and a memory 74 to receive or store a mission specification 76 for combatting the threat 4 and a prioritization 78 of the targets 5 constituting the threat 4.

FIG. 4 shows the use of an alternative autonomous scalable HPEM effector arrangement 2 for providing defense against enemy electronics in the form of the threat 4 (C-UAS, C-IED, C4I). The threat 4 is formed in this case of altogether seven targets 5 in the form of a respective drone, which are organized as a swarm 7. During operation, the effector arrangement 2 generates or emits from its sources 6 (not explicitly shown herein) HPEM pulses 36a-c in order to combat the threat 4. FIG. 4 shows at the bottom left that an alternative effector arrangement 2 is used in this case. This includes altogether three modules 8a-c, each containing a 5×5 array 10 of sources 6. The control device 22 is configured in this case as an AI device 38 or AI control and works autonomously, partially autonomously, manually or with humans in the loop.

The individual sources 6 or antenna elements and modules 8a-c in the form of the effector modules can be grouped and scaled. In the figure, this is symbolically indicated by 3 alternative activations 40a-c, which can be performed alternatively to one another with one and the same effector arrangement 2. For this purpose, sources 6 are combined into different submodules 42. For example, according to the activation 40c, in module 8a only the second and fifth columns of the array 10 (counted from the left) are activated, for 5 sources in each case, in module 8b only the third column and in module 8c only the first and fourth columns. The remaining sources 6 remain unused in this case.

Alternatively, according to the activation 40b, only in module 8c are four quadratically disposed sources 6 combined in each case to form a 4×4 submodule 42 and only altogether four such submodules are formed.

On the right in FIG. 4, the formation of submodules 42 is again indicated for one of the modules 8a with 5×5 sources 6. Within this, two submodules 42 are alternatively formed in this case. Also shown in is an alternative control device 22, which in addition to the AI device 38 contains two further control components 44.

In this case, again, the groupings of the sources 6 or antenna groupings
can be switched on.
can be specifically adapted,
can have different frequencies and frequency ranges,
activation and synchronization can take place both in a wired and a remotely controlled (RC) manner.

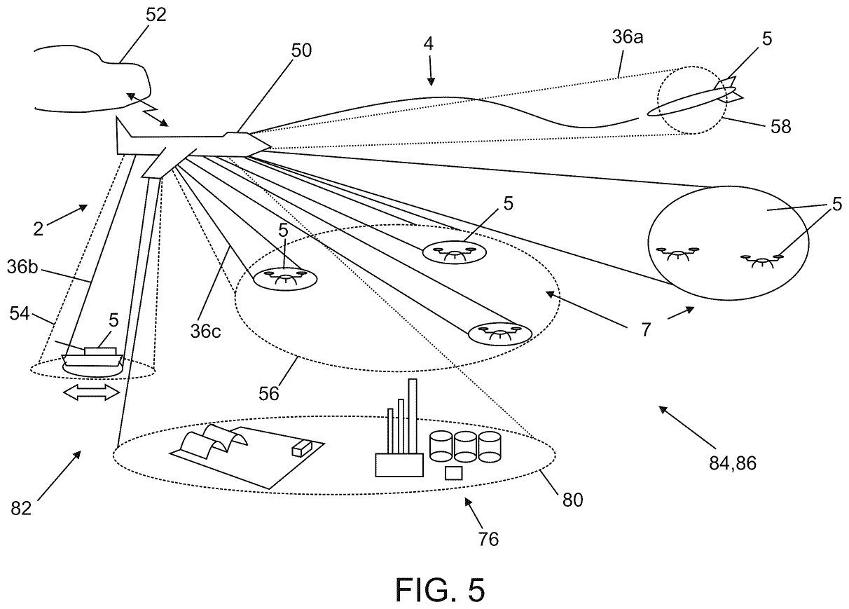

FIG. 5 shows the use of an effector arrangement 2 which is attached to an aircraft 50 and operated on it. This is in connection with a guidance system 52, which also operates in an AI-based manner. The aircraft 50 also operates in an AI-based manner.

The following applies to the effector arrangement 2:
simultaneous multi-use multi-role capability,
simultaneous counter-multi-target capability,
multi-level, multi-frequency, multi-beam capability, counter-swarm capability
HPEM beam steering and beam/pulse forming capability,
AI (detection/tracking/identification) for optimal and efficient interoperability.

In FIG. 5, this is indicated by the fact that a large number of HPEM pulses 36a-c (in this case only these three are denoted) can be emitted in order to be able to simultaneously combat the overall threat 4 in the form of a series of targets 5. A detection cone 54 together with an arrow illustrates in this case the ability to track and focus (tracking and focusing) for a target 5. Another cone 56 illustrates the ability to emit multiple beams to a number of targets 5 (multibeam capability). A circle 58 illustrates the multi-role capability of the effector arrangement 2 in which, while combatting drones as target 5, it can also simultaneously defend against other targets 5, such as an incoming missile.

FIG. 5 also symbolizes a mission specification 76 for the effector arrangement 2 in immediate use, to be specific the protection of an own industrial plant 80 from the threat 4.

FIG. 5 also illustrates a threat scenario 82. This characterizes which type of threat 4 it is, and which and how many targets 5 are involved, etc., and it also has a selection and assignment of the targets 5 or groups of targets 5, for example swarms 7, which are to be combatted. This is therefore an attack on the industrial plant 80 by a swarm of drones and at the same time an attack on the aircraft 50 by a missile.

Two target classes 84 are also detected in this case, to be specific “drone swarm” and “missile” for the corresponding targets 5. An HPEM characteristic 86 of the threat 4 or the targets 5 is therefore known, since it is known to which type of HPEM pulses 36 the targets 5 are sensitive and how many of these are necessary to successfully combat the targets 5, i.e. to eliminate them.

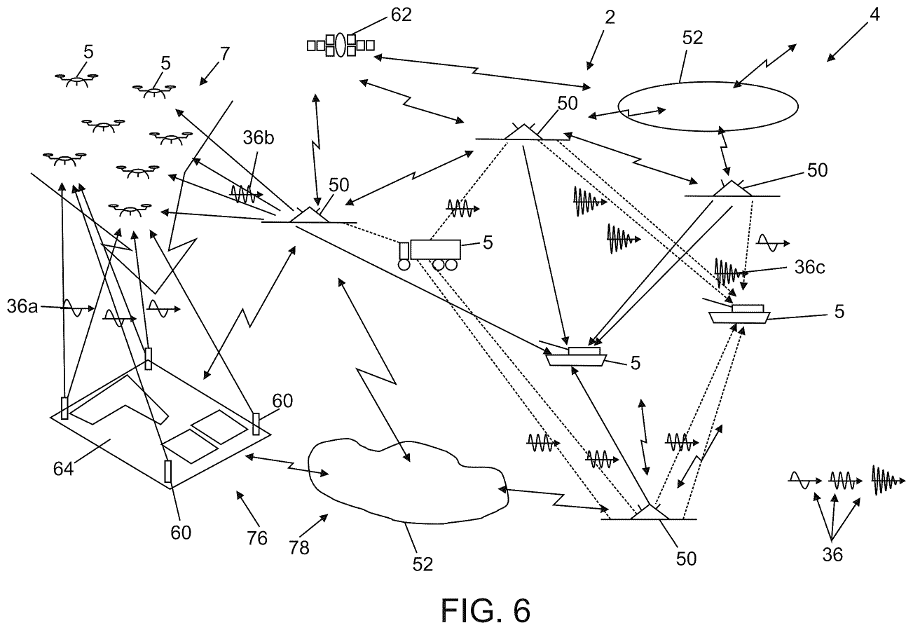

FIG. 6 shows, in a further deployment scenario, how a number of effector arrangements 2 are provided on different platforms, to be specific four aircraft 50 and stationary objects 60, in this case defensive stations of an own position 64 (field camp, military facility C4), and work together to combat a massive threat 4 including a wide variety of targets 5 such as a tank, another vehicle and a UAS swarm 7.

Two guidance systems 52 for the coordination of the effector systems 2 are also involved in this case, as well as support by a satellite 62 in the form of GPS data. As in FIG. 5, a respective communication is symbolized by a lightning-like double arrow.

The guidance systems 52 take over the coordination/target assignment and control. Different HPEM pulses 36 are indicated in the figure at the bottom right by different waveforms and are used synchronously or simultaneously to combat different targets of different sensitivity characteristics. In particular, different HPEM pulses and pulse sequences are used. The mission specification 76 in this case is the protection of the own position 64. In this case, the objects 60 protect an own position or a field camp or a military facility C4.

FIG. 6 also explains a prioritization 78: The prioritization 78 states that first defense is to be provided against the target 5 in the form of the incoming missile and then the target 5 in the form of the battle tank is to be eliminated and only finally are the two drone swarms 7 to be combatted. On the basis of the mission specification 76 and the prioritization 78, this results in a combat scenario, to be specific how and in which order the targets 5 constituting the threat 4 are to be combatted.

FIG. 7 shows a flow diagram for a method 70 for combatting a threat 4. For this purpose, an autonomous, scalable, HPEM effector arrangement 2 (effector modules) is used for providing defense against enemy electronics (C-UAS, C-IED, C4I):

The method 70 begins with a step S1. In step S1, the effector arrangement 2, i.e. the system/electronics/sensors/control, is activated/woken up. This involves an activation of the sensors (if they are not permanently active, this can be performed by a higher-level system (for example guidance system 52)).

In a step S2, the detection of the threat 4 or the targets 5 takes place as well as the identification and classification of the threat 4 or the targets 5. Similarly, a tracking of the targets 5 begins.

In a step S3, a selection and assignment of the threat scenarios 82 to the threat 4 take place.

In a step S4, the assignment of the threat 4 or the targets 5 to target classes 84 (target class) takes place. Such target classes 84 are, for example, “drone,” “battle tank,” “missile,” etc.

In a step S5, the threat 4 or the targets 5 to be combatted is/are assigned sensitivity classes in the form of HPEM characteristics 86. This happens in dependence on the assigned threat scenarios 82 and the target classes 84. The HPEM characteristics 86 state to which type of combat (number of pulses, duration, frequency, amplitude, . . . ) the respective target 5 or the threat 4 is sensitive, so that correspondingly suited HPEM measures, which in this case promise high effectiveness against the threat 4, can be selected.

In a step S6, the assignment/selection of the required/most efficient pulse shapes and frequency ranges and bandwidths to the targets/target groups/target classes 84 follows. Thus, the characteristics according to which the sources 6 or modules 8a-c are to be activated or operated are determined.

In a step S7, the selection, activation and synchronization of the modules 8a-c/submodules 42 (subsystems)/antennas which are best suited to implement the characteristics of the sources 6 determined in step S6 take place.

In steps S6 and S7, the assignment of the threat 4 to the HPEM sources 6 therefore takes place depending on the assigned threat scenarios 82 and the assigned target classes 84 and the assigned HPEM characteristics 86.

In a step S8, the determination of the mission specifications 76 and the prioritization 78 or the decisions concerned takes place. These are then introduced into the effector arrangement 2 by way of the input 72, are stored in the memory 74 or are removed from it. This corresponds to or accompanies the selection of combat scenarios/modes to counter the threat 4. Thus, the mission specification 76 and the prioritization 78 are provided in the method 70.

In a step S9, the actual activation, setting and synchronization of the modules 8a,b, sources 6 or the systems take place. Thus, the actual combatting of the threat 4, i.e. the targets 5, takes place. The activation of the sources 6 to combat the threat 4 therefore takes place in this case depending on the assigned threat scenarios 82 and the assigned target classes 84 and the assigned HPEM characteristics 86 and the mission specifications 76 and the prioritizations 78.

In a step S10, the verification of the combat takes place.

The following is a summary list of reference numerals and the corresponding structure used in the above description of the invention:
2 Effector arrangement
4 Threat
5 Target
6 HPEM source
7 Swarm
8a-c Module
10 Array
12 Feed network
14 Energy supply
16 Primary energy
18 Buffer
20 Block
22 Control device
24 Block
26 Monopole
28 Dipole
30 Spiral antenna
32 Arrow
34 Arrow
36,36a-c HPEM pulse
38 AI device
40a-c Activation
42 Submodule
44 Control component
50 Aircraft
52 Guidance system
54 Cone
56 Cone
58 Circle
60 Object
62 Satellite
64 Position
70 Method
72 Input
74 Memory
76 Mission specification
78 Prioritization
80 Industrial plant
82 Threat scenario
84 Target class
86 HPEM characteristic
n Column
m Row
a,b,c Dimension
S1-10 Step

1. An effector arrangement for combatting a threat in the form of at least one target, the effector arrangement comprising:
at least two HPEM sources configured to emit respective HPEM pulses to the threat;
at least two of said HPEM sources configured to be activated independently of one another for an emission of the HPEM pulses;
at least one of an input or a memory for at least one of at least one mission specification or at least one prioritization of targets in relation to combatting the threat;
a control device configured:
to assign at least one of a plurality of predefinable threat scenarios to the threat;
to assign at least one of a plurality of predefinable target classes to the threat;
to assign at least one of a plurality of predefinable HPEM characteristics depending on at least one of the assigned threat scenarios or the assigned target classes to the threat;
to assign at least one of the HPEM sources depending on at least one of the assigned threat scenarios or the assigned target classes or the assigned HPEM characteristics to the threat; and
to activate the assigned HPEM sources depending on:
at least one of the assigned threat scenarios or the assigned target classes or the assigned HPEM characteristics, and
at least one of the mission specifications or the prioritizations,
to combat the threat.

2. The effector arrangement according to claim 1, wherein at least one of the target classes is a target class specifically adapted to a sensitivity of the target with respect to HPEM pulses.

3. The effector arrangement according to claim 1, which further comprises at least one module containing at least one of said HPEM sources.

4. The effector arrangement according to claim 3, wherein said at least one module includes at least one module configured as a semiconductor-based fully integrated module.

5. The effector arrangement according to claim 3, wherein said at least one module includes at least one module containing at least two of said HPEM sources disposed as an array in a fixed relative position in relation to one another.

6. The effector arrangement according to claim 1, wherein:
said at least two HPEM sources include at least three HPEM sources being optionally and modifiably combined to form submodules each having at least two respective HPEM sources; and
said control device is configured to activate said HPEM sources organized as said current submodule jointly and independently of other HPEM sources.

7. The effector arrangement according to claim 1, wherein said control device is configured to operate the effector arrangement for at least two of the targets of the threat in parallel and independently of one another.

8. The effector arrangement according to claim 1, wherein said control device is configured to activate at least two of said HPEM sources by synchronizing said at least two HPEM sources with one another for emitting the HPEM pulses.

9. The effector arrangement according to claim, 1 wherein said control device contains or is an AI device.

10. A method for combatting a threat in the form of at least one target by using an effector arrangement, the method comprising:
providing the effector arrangement according to claim 1 having at least one of at least one mission specification or at least one prioritization of targets in relation to combatting the threat;
using said control device to:
assign at least one of a plurality of predefinable threat scenarios to the threat;
assign at least one of a plurality of predefinable target classes to the threat;
assign at least one of a plurality of predefinable HPEM characteristics depending on at least one of the assigned threat scenarios or the assigned target classes to the threat;
assign at least one of said HPEM sources depending on at least one of the assigned threat scenarios or the assigned target classes or the assigned HPEM characteristics to the threat; and
activate the assigned HPEM sources depending on:
at least one of the assigned threat scenarios or the assigned target classes or the assigned HPEM characteristics, and
at least one of the mission specifications or the prioritizations, to combat the threat.
